(19) United States
(12) Patent Application Publication
(10) Pub. No.: US 2019/0157591 A1
(43) Pub. Date: May 23, 2019

(54) THIN FILM TRANSISTOR AND METHOD FOR FORMING THE SAME, ARRAY BASEPLATE, AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventors: Miao Yuan, Beijing (CN); Qiyu Shen, Beijing (CN); Xufei Xu, Beijing (CN); Jianying Zhan, Beijing (CN); Haibing Guo, Beijing (CN)

(73) Assignees: BOE TECHNOLOGY GROUP CO., LTD., Beijing (CN); HEFEI BOE OPTOELECTRONICS TECHNOLOGY CO., LTD., Hefei, Anhui (CN)

(21) Appl. No.: 15/758,970

(22) PCT Filed: Sep. 13, 2017
(86) PCT No.: PCT/CN2017/101539

§ 371 Date: Mar. 9, 2018

(30) Foreign Application Priority Data
Jan. 12, 2017 (CN) 201710023214.4

(51) Int. Cl. H01L 51/05; H01L 29/786; H01L 51/00

(52) U.S. Cl. CPC H01L 51/0558; H01L 29/78603; H01L 51/0545; H01L 51/0005; H01L 51/0012

(57) ABSTRACT

Embodiments of the present disclosure relate to the display technical field and provide a thin film transistor and a method for producing the same, an array baseplate, and a display device. The method for producing the thin film transistor includes forming an active layer which includes: forming a plurality of processing regions along a first direction on a substrate, where any two adjacent processing regions have different hydrophilicities and the first direction is parallel with the transmission direction of carriers in the thin film transistor, forming an active layer on the substrate to cover at least part of a junctional region between two adjacent processing regions.

### CROSS-REFERENCE TO RELATED APPLICATIONS

This application is based upon and claims the priority of Chinese Patent Application No. 201710023214.4 filed on Jan. 12, 2017, the entire contents of which are hereby incorporated by reference herein for all purposes.

### TECHNICAL FIELD

The present disclosure relates to the display technical field, especially, relates to a thin film transistor and a method for forming the same, an array baseplate, and a display device.

### BACKGROUND

A Thin Film Transistor Liquid Crystal Display (TFT-LCD), as a panel display device, is increasingly applied to the high-performance display field due to its characteristics such as small volume, low power consumption, radiation free and relatively low production cost.

Specifically, the thin film transistors include inorganic thin film transistors and organic thin film transistors (OTFT) where the OTFT may be used to produce smaller devices. The OTFT has a better flexibility and thus may be used to produce flexible displays.

### SUMMARY

The present disclosure provide a thin film transistor and a method for forming the same, an array baseplate, and a display device.

The present disclosure provides a method for fabricating a thin film transistor. The method may include forming an active layer, wherein forming the active layer may include: forming a plurality of processing regions on a substrate along a first direction where any two adjacent processing regions have different hydrophilicities, and the first direction is parallel with a transmission direction of carriers in the thin film transistor, and forming an active layer on the substrate to cover at least part of a junctional region between two adjacent processing regions.

Optionally, forming the plurality of processing regions on the substrate may include placing the plurality of processing regions successively along the first direction.

Optionally, forming the plurality of processing regions on the substrate may include enabling the hydrophilicities of the processing regions to change successively and gradually along the first direction.

Optionally, the processing regions along a second direction covered by the active layer may have an equal size, and the second direction may be perpendicular to the first direction.

Optionally, forming the plurality of processing regions on the substrate may include forming the plurality of the processing regions on the substrate by performing a ultraviolet (UV)-irradiation process.

Optionally, performing the UV-irradiation process may include: providing a light-radiation mask on a side of the substrate to be irradiated; irradiating the substrate through a photic zone on the light-radiation mask with an UV mercury lamp; and moving the substrate or the light-radiation mask along the first direction at a constant speed.

Optionally, performing the UV-irradiation process may include: providing a light-radiation mask on a side of the substrate to be irradiated; and irradiating the substrate through a photic zone on the light-radiation mask with a plurality of low pressure UV mercury lamps having different illumination intensities at a same radiation period.

Optionally, performing the UV-irradiation process may include: providing a light-radiation mask on a side of the substrate to be irradiated; and irradiating the substrate through a photic zone on the light-radiation mask with a plurality of low pressure UV mercury lamps having identical illumination intensity and different illumination periods.

Optionally, the light-radiation mask is identical to a mask for producing the active layer.

Optionally, forming the active layer on the substrate may include: applying an organic semiconductor solution on the substrate; and causing the organic semiconductor solution to dry into a film to form the active layer.

Optionally, before applying the organic semiconductor solution on the substrate, the method may further include: forming a layer of resist on the substrate; removing part of the resist by performing a patterning process to form a resist removal region; where applying the organic semiconductor solution on the substrate may include applying the organic semiconductor solution on a position of the substrate corresponding to the resist removal region.

Optionally, before forming the plurality of processing regions on the substrate along a first direction, the method may further include: forming, by performing a patterning process, a gate electrode and a gate insulating layer successively on a substrate baseplate, where the gate insulating layer may be the substrate.

Optionally, the substrate may be the substrate baseplate; and after the forming the active layer on the substrate to cover at least part of the junctional region between two adjacent processing regions, the method may further include: forming, by performing a patterning process, a gate insulating layer and a gate electrode successively on the substrate baseplate on which the active layer is formed; and forming, by performing the patterning process, the source electrode and the drain electrode on the substrate baseplate on which the gate electrode is formed.

Optionally, the active layer may be formed by using a polar semiconductor material.

Optionally, a solvent of the organic semiconductor solution may include a polar solvent.

In another aspect of the embodiments of the present disclosure, a thin film transistor produced by the above method is provided. The thin film transistor may include a source electrode and a drain electrode, and a substrate and an active layer on the substrate; where the active layer may be formed by using an organic semiconductor material, and a growth direction of crystals of the active layer is parallel with a transmission direction of carriers in the thin film transistor.

Optionally, the thin film transistor may further include a gate electrode and a gate insulating layer that are successively placed on a substrate baseplate; and the gate insulating layer may be the substrate.

Optionally, the thin film transistor may further include a gate insulating layer and a gate electrode that may be successively placed on the substrate baseplate; the substrate baseplate may be the substrate, and the active layer may be located between the substrate baseplate and the gate insulating layer.

In a further aspect of the embodiments of the present disclosure, an array baseplate is provided. The array baseplate may include any one of the thin film transistors described above.

In a still further aspect of the embodiments of the present disclosure, a display device is provided. The display device may include the array baseplate described above.

It is to be understood that both the forgoing general description and the following detailed description are exemplary only, and are not restrictive of the present disclosure.

### BRIEF DESCRIPTION OF THE DRAWINGS

To illustrate the embodiments of the present disclosure or the technical solutions in the prior art, more clearly drawings required for embodiments or prior art are briefly introduced as follows. Apparently, the drawings as illustrated below are merely some of the embodiments of the present disclosure. Those skilled in the art would also conceive other drawings according to these ones without any inventive efforts.

FIG. 1 illustrates a schematic diagram of crystal boundary direction in an active layer of a thin film transistor provided in the prior art;

FIG. 2 illustrates a flow chart illustrating a method for producing a thin film transistor provided in an embodiment of the present disclosure;

FIG. 3 illustrates a schematic diagram of forming processing regions on a substrate provided in an embodiment of the present disclosure;

FIG. 4 illustrates a schematic diagram of the active layer covering part of a junctional region between two adjacent processing regions having different hydrophilicities shown in FIG. 3;

FIG. 5 illustrates a top view of the structure shown in FIG. 4;

FIG. 6 illustrates a schematic diagram of an organic semiconductor solution covering part of a junctional region between two adjacent processing regions having different hydrophilicities shown in FIG. 3;

FIG. 7 illustrates a schematic diagram illustrating a drying tendency of the organic semiconductor solution in FIG. 6;

FIG. 8 illustrates a schematic diagram of the organic semiconductor solution in FIG. 7 after it is completely dried;

FIG. 9 illustrates a schematic diagram of another formation of processing regions on the substrate provided in an embodiment of the present disclosure;

FIG. 10 illustrates a flow chart illustrating a method for producing a bottom-gate type thin film transistor provided in an embodiment of the present disclosure;

FIG. 11 illustrates a schematic diagram of producing a structure having a gate electrode and a gate insulating layer by step S201 in FIG. 10;

FIG. 12 illustrates a schematic diagram of forming processing regions on the gate insulating layer by step S202 in FIG. 10;

FIG. 13 illustrates a schematic diagram of a moving state of a light-radiation mask in FIG. 12;

FIG. 14 illustrates a schematic diagram of another moving state of the light-radiation mask in FIG. 12;

FIG. 15 illustrates a schematic diagram of forming the organic semiconductor solution by step S203 in FIG. 10;

FIG. 16 illustrates a schematic diagram of forming the active layer by step S204 in FIG. 10;

FIG. 17 illustrates a structure schematic diagram of forming the bottom-gate type thin film transistor by step S205 in FIG. 10;

FIG. 18 illustrates a structure schematic diagram of a top-gate type thin film transistor provided in an embodiment of the present disclosure.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various examples of the present disclosure. Also, common but well-understood elements that are useful or necessary in a commercially feasible example are often not depicted in order to facilitate a less obstructed view of these various examples. It will further be appreciated that certain actions and/or steps may be described or depicted in a particular order of occurrence while those skilled in the art will understand that such specificity with respect to sequence is not actually required. It will also be understood that the terms and expressions used herein have the ordinary technical meaning as is accorded to such terms and expressions by persons skilled in the technical field as set forth above, except where different specific meanings have otherwise been set forth herein.

### DETAILED DESCRIPTION

The technical solutions in embodiments of the present publication are to be further elaborated in detail with reference to the accompanying drawings in embodiments of the present disclosure. Apparently, the embodiments elaborated are merely a part of embodiments of the present disclosure instead of all of them. Based on the embodiments in the present disclosure, all other embodiments obtained by one of ordinary skills in the art without inventive efforts belong to the protection scope sought to be protected in the present disclosure.

The terminology used in the present disclosure is for the purpose of describing exemplary examples only and is not intended to limit the present disclosure. As used in the present disclosure and the appended claims, the singular forms “a,” “an” and “the” are intended to include the plural forms as well, unless the context clearly indicates otherwise. It shall also be understood that the terms “or” and “and/or” used herein are intended to signify and include any or all possible combinations of one or more of the associated listed items, unless the context clearly indicates otherwise.

It shall be understood that, although the terms “first,” “second,” “third,” etc. may be used herein to describe various information, the information should not be limited by these terms. These terms are only used to distinguish one category of information from another. For example, without departing from the scope of the present disclosure, first information may be termed as second information; and similarly, second information may also be termed as first information. As used herein, the term “if” may be understood to mean “when” or “upon” or “in response to” depending on the context.

Reference throughout this specification to “one embodiment,” “an embodiment,” “exemplary embodiment,” or the like in the singular or plural means that one or more particular features, structures, or characteristics described in connection with an example is included in at least one embodiment of the present disclosure. Thus, the appearances of the phrases “in one embodiment” or “in an embodiment,” “in an exemplary embodiment,” or the like in the singular or plural in various places throughout this specification are not necessarily all referring to the same embodiment. Furthermore, the particular features, structures, or characteristics in one or more embodiments may be combined in any suitable manner.

The reference provided in drawings are as follows: 01—substrate; 02—substrate baseplate; 10—active layer; 101, 101′-processing region; 111—junctional region; 11—source electrode; 12—drain electrode; 13—gate electrode; 14—gate insulating layer; 15—resist; 151—resist removal region; 16—light-radiation mask; 161—photic zone; 162—shading zone; 17—passivation layer, 20—organic semiconductor solution.

The present disclosure provides a thin film transistor and a method for producing the same, an array baseplate, and a display device. The method for producing the thin film transistor includes a procedure for producing a source electrode and a drain electrode. In addition, the method also includes a procedure for producing the active layer: first, a plurality of processing regions are formed on a substrate along a first direction where any two adjacent processing regions have different hydrophilicities, and the first direction is parallel with the transmission direction of carriers in the thin film transistor. Next, an active layer at least covering part of a junctional region between two adjacent processing regions is formed on the substrate.

It can be known from the above, a plurality of processing regions formed on the substrate are arranged along the first direction, and any two adjacent processing regions have different hydrophilicities. Thus, the wettabilities of the above any two adjacent processing regions on substrate surface along the first direction vary in a gradient manner. In such a condition, when an active layer at least covers part of a junctional region between two adjacent processing regions that is formed on the substrate, the crystals in the active layer may grow in the above direction along which the wettabilities vary in a gradient manner, namely, the first direction.

As such, the direction of most of the crystal boundaries in the active layer is parallel with the above first direction. During the conduction of the thin film transistor, the transmission direction of carriers is parallel with the above first direction. As such, there are a great number of crystal boundaries parallel with the transmission direction of carriers in the active layer, and accordingly, the number of crystal boundaries perpendicular to the transmission direction of carriers may correspondingly decrease. The migration speed of the carriers is enhanced, and the aims may be achieved for enhancing the migration rate and electrical properties of the thin film transistor, and uniforming electrical properties of the same.

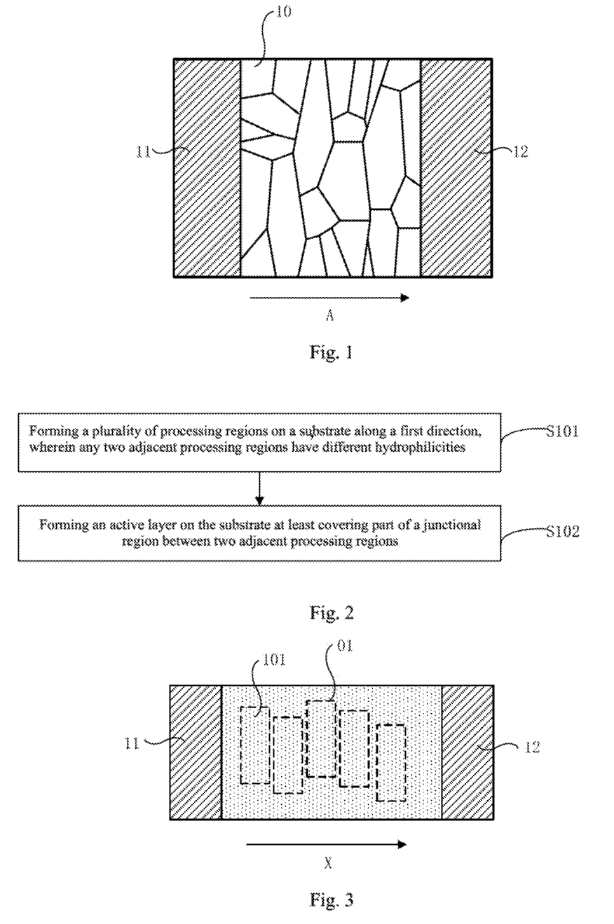

During the processes for producing organic thin film transistors (OTFT), a gate electrode and a gate insulating layer are formed on a substrate baseplate by performing a patterning process, and then an organic semiconductor solution is applied on the gate insulating layer by using an ink-jet printing process. As shown in FIG. 1, after being dried, the organic semiconductor solution forms an active layer 10. Then, a source electrode 11 and a drain electrode 12 are formed by performing a patterning process.

However, the organic semiconductor solution demonstrates isotropy during the drying process of gate insulating layer interfaces. Accordingly, the film-forming direction and speed of films formed during the drying process have certain randomness. As such, the profiles of the films formed are difficult to be controlled. Also, in the film of active layer 10 as shown in FIG. 1, the crystallization direction is disordered. Under such a condition, the crystal boundaries in the above-mentioned film of active layer 10 may be perpendicular to a transmission direction A of carriers in an OTFT channel and affect the migration speed of the carriers. Thus, the migration rate of OTFT may be reduced.

As shown in FIG. 2, the present disclosure provides a method for producing a thin film transistor. The method may include performing a procedure for producing a source electrode and a drain electrode, and performing a procedure for producing an active layer.

S101: A plurality of processing regions 101 are formed on a substrate 01 shown in FIG. 3 along a first direction X, and any two adjacent processing regions 101 may have different hydrophilicities.

As such, the wettabilities of any two adjacent processing regions 101 on the surface of substrate 01 along the first direction X may vary in a gradient manner.

The above first direction X may be parallel with the transmission direction of carriers in the thin film transistor. The first direction X may be identical or opposite to the transmission direction A of carriers in the thin film transistor. For the illustration purpose, the following description is based on that the first direction X is identical to the transmission direction A of carriers in the thin film transistor.

In addition, the embodiments of the present disclosure do not limit the type and structure of the thin film transistor. For example, the thin film transistor may be an N-type transistor or a P-type transistor. Further, the source electrode 11 and the drain electrode 12 of the thin film transistor may be shaped in blocks and may be located oppositely as provided in FIG. 3. The source electrode 11 of the thin film transistor may be in a block shape, while the drain electrode 12 may be in a single-U-shape or a double-U-shape.

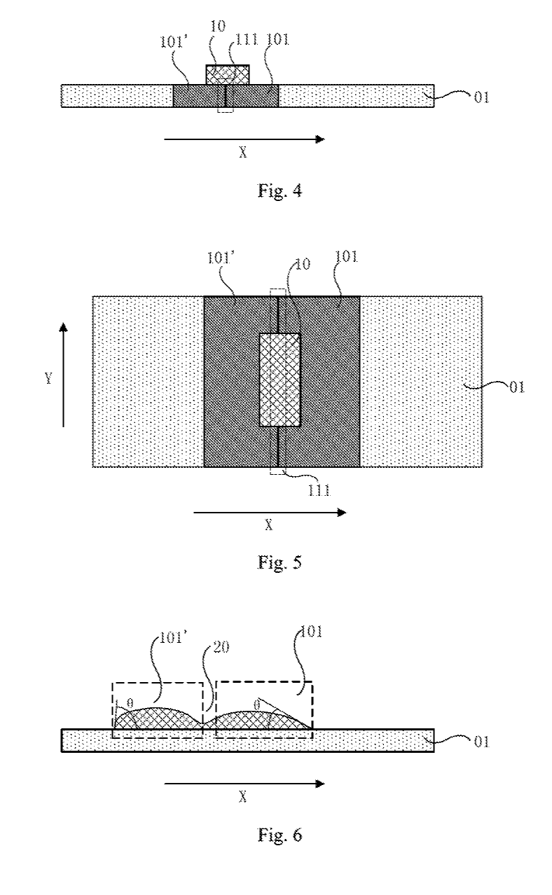

S102: As shown in FIG. 4, on the substrate 01, an active layer 10 is formed at least to cover part of a junctional region 111 between two adjacent processing regions marked as 101 and 101′.

As shown in FIG. 5, an active layer 10 at least covering part of a junctional region 111 refers to that the size of the active layer 10 may be smaller than the size of the junctional region 111. The active layer 10 may be along a second direction Y that is perpendicular to the first direction X.

As such, a plurality of processing regions formed on the substrate may be arranged along the first direction, and any two adjacent processing regions have different hydrophilicities. The wettabilities of the two adjacent processing regions on the substrate surface along the first direction may vary in a gradient manner.

Thus, when an active layer at least covering part of a junctional region between two adjacent processing regions is formed on the substrate, the crystals in the active layer would grow in the above direction along which the wettabilities vary in a gradient manner, namely, the first direction. The direction of most of the crystal boundaries in the active layer is parallel with the above first direction.

During the conduction of the thin film transistor, the transmission direction of carriers may be parallel with the above first direction. As such, there are a great number of crystal boundaries parallel with the transmission direction of carriers in the active layer and accordingly, the number of crystal boundaries perpendicular to the transmission direction of carriers may correspondingly decrease. The migration speed of the carriers may thus be enhanced, the aims can be achieved for enhancing the migration rate and electrical properties of the thin film transistor, and uniforming of electrical properties of the same.

As shown in FIG. 6, the method for forming an active layer 10 on a substrate 01 may include: an organic semiconductor solution 20 is applied and formed on the substrate 01. The organic semiconductor solution 20 may be applied and formed by performing an ink-jet printing process.

The above organic semiconductor solution 20 may need to at least cover part of a junctional region 111 between two adjacent processing regions (101 and 101′), such that the active layer 10 obtained by film-formation may at least cover part of the junctional region 111 between two adjacent processing regions 101 and 101′ as shown in FIG. 5.

In addition, as shown in FIG. 6, the organic semiconductor solution 20 has a great contact angle θ on the surface of substrate 01 with a small wettability where on the surface the processing region 101′ is located. The organic semiconductor solution 20 has a small contact angle θ on the surface of substrate 01 with a great wettability where on the surface the processing region 101 is located.

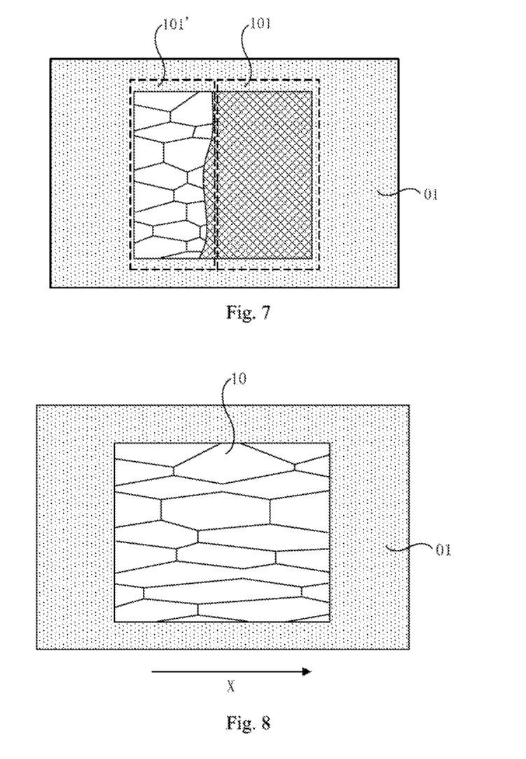

Therefore, when the organic semiconductor solution 20 at least covers part of the junctional region 111 between two adjacent processing regions 101 and 101′ as shown in FIG. 7, the organic semiconductor solution 20 may dry gradually from the surface of substrate 01 with a small wettability where the surface the processing region 101′ is located, namely, the hydrophobic end, to the surface of substrate 01 with a great wettability where the surface the processing region 101 is located, namely, the hydrophilic end. As such, the crystals in the organic semiconductor solution 20 contacting with the surface of substrate 01 are of different wettabilities that may grow in the above direction along which the wettabilities vary in a gradient manner, namely, the first direction X. Accordingly, in the organic semiconductor solution 20, the crystal growth direction may follow certain regularity, and because of that, the possibility that the crystals grow randomly may be reduced.

The above organic semiconductor forming the active layer 10 may be selected from at least one of the group consisting of 6,13 Bis(triisopropylsilylethynyl)pentacene (TIPS pentacene), dibenzothiophene (BTBT), and derivatives thereof. Thus, to enhance the surface polarity of the organic semiconductor solution 20 so that the diffusion gradient of the organic semiconductor solution 20 on the surface of substrate 01 varies more evidently, the materials forming the active layer may include a polar organic semiconductor material, for example:

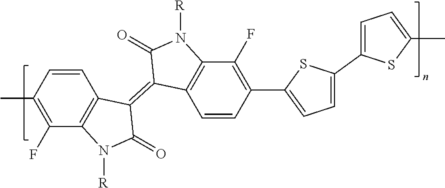

or for another example:

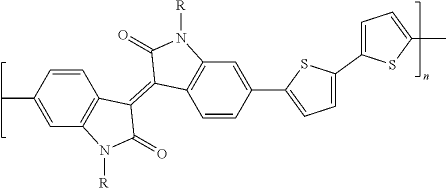

where the functional group R is:

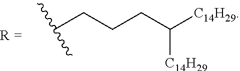

In addition, the solvent of the above organic semiconductor solution 20 may be a polar solvent, where the materials forming the polar solvent may be selected from tetrahydrofuran, dichloromethane and the like.

The above organic semiconductor solution 20 may be dried into a film to form the active layer 10.

The materials forming the active layer 10 may include an organic semiconductor material. Accordingly, the thin film transistor having the active layer 10 may be an organic thin film transistor.

The organic semiconductor solution 20 may be air-dried naturally to form the active layer 10. Alternatively, to enhance the production efficiency, the organic semiconductor solution 20 may also be dried by performing a high-temperature heating process.

Since the crystals in the organic semiconductor solution 20 may grow in the direction along which the wettabilities vary in a gradient manner, namely, the above first direction X, the active layer 10 may obtained after film formation as shown in FIG. 8. In FIG. 8, the direction of most of the crystal boundaries in the active layer 10 is parallel with the first direction X.

During the conduction of the thin film transistor, the transmission direction A of carriers is parallel with the first direction X. As such, there are a great number of crystal boundaries parallel with the transmission direction A of carriers in the active layer 10. Accordingly, the number of crystal boundaries that is perpendicular to the transmission direction A of carriers may correspondingly decrease, and the diameters of the crystals produced along the above transmission direction A of carriers may increase. Thus, the migration speed of the carriers is enhanced, and the aim is achieved for enhancing the migration rate and conductivity of the thin film transistor.

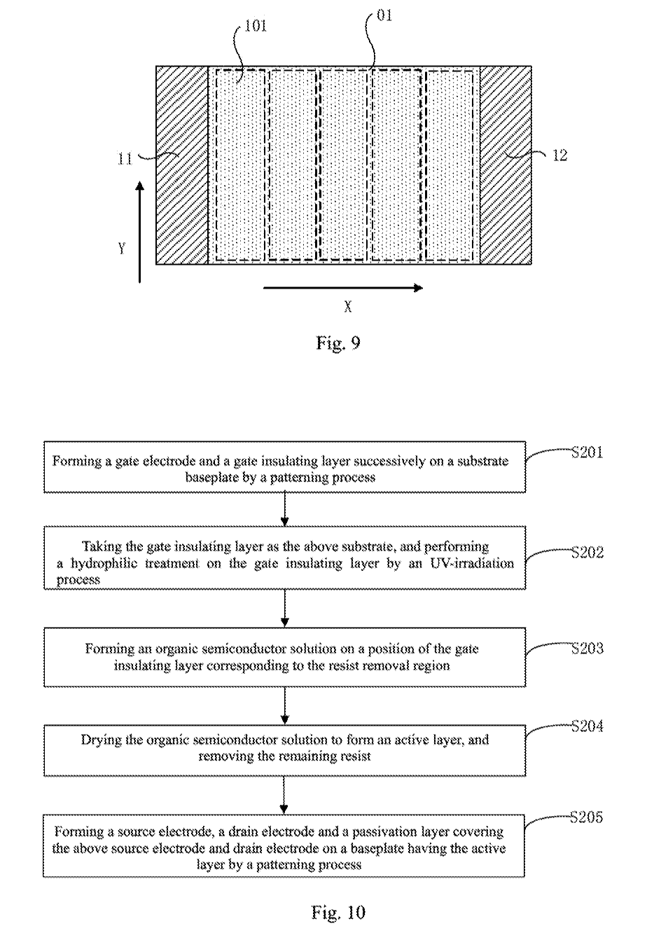

To further increase the number of crystals regularly growing in the organic semiconductor solution 20, the plurality of processing regions 101 formed in step S101 shown in FIG. 9 may be placed successively and closely along the first direction X. As such, the arrangement of the plurality of processing regions 101 may be in order. The organic semiconductor solution 20 may cover orderly arranged the plurality of processing regions 101. Thus, under the effect of a plurality of adjacent two processing regions 101 having different hydrophilicities, more crystals in the organic semiconductor solution 20 may grow along the above first direction X when the plurality of processing regions 101 are placed orderly.

In order to improve the uniformity of crystals during the growth, the hydrophilicities of the plurality of processing regions 101 formed in step S101 may change successively and gradually along the first direction X. The gradient variation degree of wettability of the portion on the surface of substrate 01 used for contacting with the organic semiconductor solution 20 may become more refined. Thus, after the organic semiconductor solution 20 gradually dries in the direction along which the hydrophilicities gradually increase and after the organic semiconductor solution 20 covering two adjacent processing regions 101 is dried into a film, the crystals in the film may distribute more orderly and uniformly.

It should be noted that the hydrophilicities of the above plurality of processing regions 101 may vary gradually. The hydrophilicities of the plurality of processing regions 101 may gradually decrease successively along the transmission direction A of carriers, or gradually increase successively along the transmission direction A of carriers.

In addition, to further increase the number of crystals regularly growing in the organic semiconductor solution 20, as shown in FIG. 9, all the processing regions 101 covered by the organic semiconductor solution 20 along the second direction Y may have equal sizes, and the second direction Y may be perpendicular to the first direction X.

Thus, the more the number of processing regions 101 covered by the organic semiconductor solution 20 is, with the hydrophilicities of the plurality of processing regions 101 changing gradually and successively, the more the number of crystals in the organic semiconductor solution 20 grow regularly. As such, any or all portion of the organic semiconductor solution 20 may cover the processing regions 101.

In such a condition, it is feasible to form a plurality of processing regions 101 arranged successively and closely. The plurality of processing regions 101 may have successively and gradually varying hydrophilicities on the position of the substrate 01 where the active layer 10 is to be formed, on the substrate 01. The size of each processing region 101 along the above second direction Y may be equal or similar to the size of the active layer 10 to be formed along the second direction Y.

In this way, after the organic semiconductor solution 20 is applied and formed by performing an ink-jet printing process on a position of the substrate 01 where the corresponding to the position is where the active layer 10 is to be formed, the organic semiconductor solution 20 may cover most of the processing regions 101.

Further, under the effect of a plurality of processing regions 101, the hydrophilicities of which may gradually and successively vary along the first direction X, the organic semiconductor solution 20 may gradually dry in the direction along which the hydrophilicities increases gradually and successively. The semiconductor molecules for forming the active layer 10 may grow along the first direction, and may be parallel with the drying direction of the organic semiconductor solution 20. The active layer 10 may thus be formed as shown in FIG. 8. In FIG. 8, most of the crystal boundaries in the active layer 10 are parallel with the first direction X or are parallel with the transmission direction A of carriers. As such, after the conduction of the thin film transistor, the carriers are transmitted more smoothly, and the migration rate of thin film transistor is greatly enhanced.

It should be noted that in the present disclosure, a plurality of the processing regions 101 are formed on the substrate 01 by a hydrophilic treatment. The hydrophilic treatment may improve the hydrophilic degree of treated interface by forming active groups on the treated interface. The above hydrophilic treatment may include performing a plasma treatment process, or performing an UV-irradiation process. The examples of performing UV-irradiation process are described as follows.

For example, if taking a bottom-gate type thin film transistor as an example, when the above active layer 10 is formed by the UV-irradiation process, the bottom-gate type thin film transistor may be produced by using a method shown in FIG. 8. The method may include:

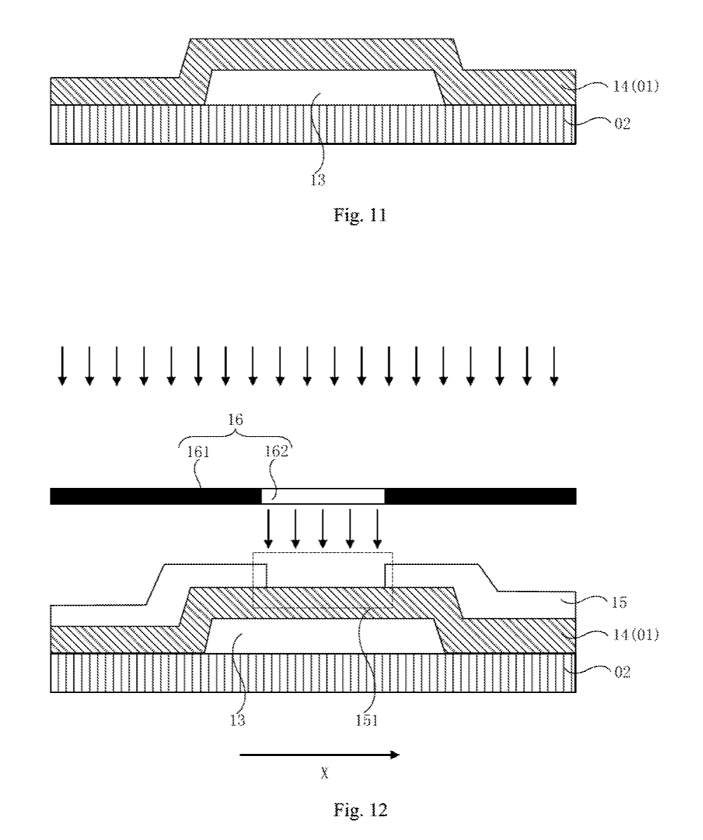

S201: A gate electrode 13 and a gate insulating layer 14 are formed by performing the patterning process successively on a substrate baseplate 02 as shown in FIG. 11.

It should be noted that the substrate baseplate 02 may be a transparent resin baseplate or glass baseplate. In the present disclosure, the patterning process may include a photolithographic process, or may include a photolithographic process and an etching step. The patterning process may also include other processes such as printing including inkjet printing for forming a predetermined pattern. The photolithographic process may refer to a process for forming patterns, which includes film-forming, exposure, development and other technical processes by using resist, mask and exposure machine. The patterning process to be performed may be selected according to the structure formed in the present disclosure.

In the one-patterning process in an embodiment of the present disclosure, the following process is described as an example. The different exposure regions may be formed in a one-mask exposure process, and then the different exposure regions may undergo multiple times of removal process such as etching and ashing to finally obtain the intended pattern.

S202: The gate insulating layer 14 is used as the substrate 01, and the gate insulating layer 14 undergoes a hydrophilic treatment by performing an UV-irradiation process.

As shown in FIG. 12, before step S202, the method for producing a thin film transistor may further include: a layer of resist 15 is formed on the substrate 01, namely, gate insulating layer 14; and then part of the resist 15 is removed by the one-patterning process to form a resist removal region 151.

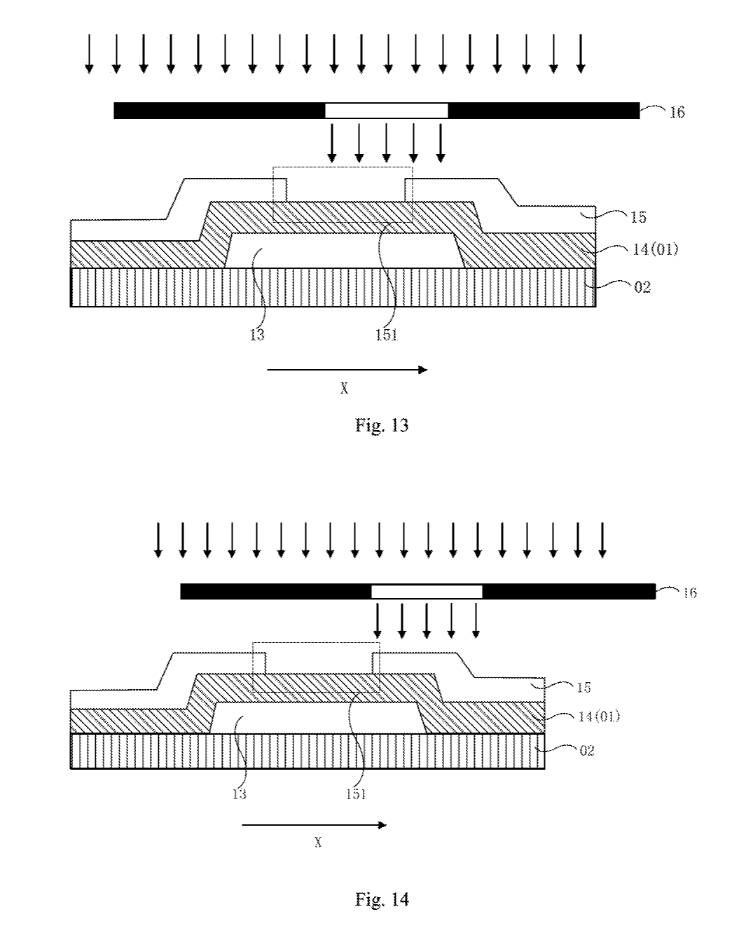

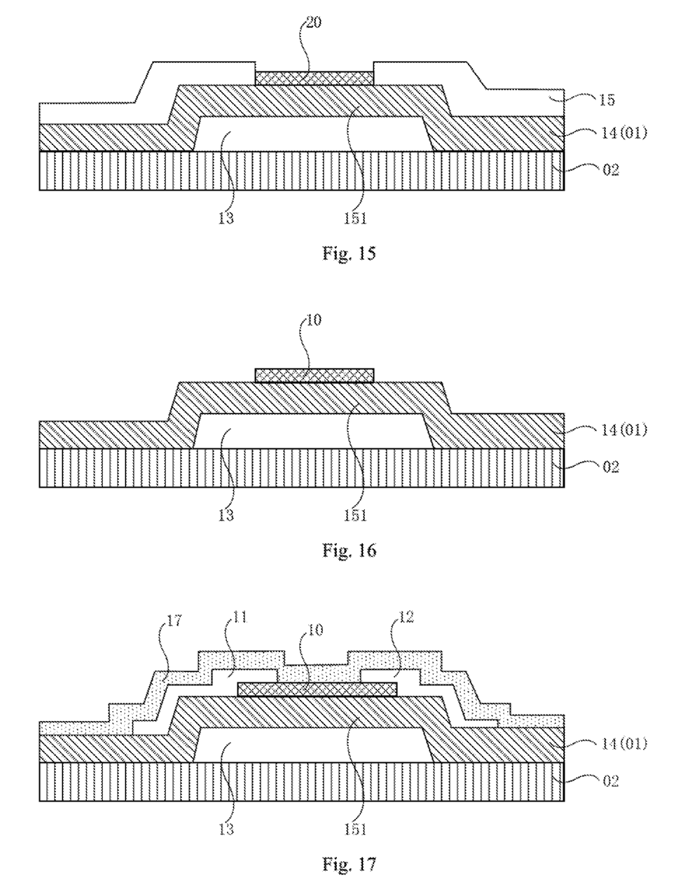

The step S202 may include: first a light-radiation mask 16 is provided on one side of the gate insulating layer 14 to be irradiated. The light-radiation mask 16 may include a photic zone 161 and a shading zone 162. The photic zone 161 corresponds to the position opposite the resist removal region 151. Next, an UV mercury lamp, such as a low pressure UV mercury lamp, irradiates the substrate 01, namely, the gate insulating layer 14, via the photic zone 161 of the light-radiation mask 16. Lastly, a baseplate formed with the gate insulating layer 14 is moved along the first direction X at a constant speed. Alternatively, as shown in FIG. 13, the light-radiation mask 16 is moved along the first direction X at a constant speed, to finally move the photic zone 161 of the light-radiation mask 16 gradually away from the above resist removal region 151 as shown in FIG. 14.

It should be noted that the low pressure UV mercury lamp may emit two types of UV-lights having wavelengths of 254 nm and 185 am simultaneously during irradiation. The UV-light having a wavelength of 185 nm may disintegrate the oxygen in the air into ozone, and the UV-light having a wavelength of 254 am may disintegrate the ozone into oxygen and active oxygen.

In the UV-lights having the above two wavelengths, the photon energy may open and cleave the irradiated interface, which is the covalent bonds in the above gate insulating layer 14, and bond the H atoms and C atoms in the cleaved and opened covalent bonds with the active oxygen obtained from disintegration to produce active groups such as hydroxyl group. As such, the active groups contribute to enhance the hydrophilicity of the organic semiconductor solution 20 on the surface of gate insulating layer 14.

Specifically, the longer time the low pressure UV mercury lamp irradiates, the more active groups may be produced in the gate insulating layer 14 irradiated, and the more hydrophilic the surface becomes. Thus, when the light-radiation mask 16 is moved along the first direction X at a constant speed, the position on the surface of gate insulating layer 14 corresponding to the resist removal region 151 may receive successively increased durations of UV-irradiation along the first direction X. Thus, a plurality of processing regions 101 having successively increasing hydrophilicities and arranged successively and closely may be formed on the positions.

S203: As shown in FIG. 15, the organic semiconductor solution 20 is applied and formed on a position of the gate insulating layer 14 corresponding to the resist removal region 151. As such, the resist 15 may confine the edge of the organic semiconductor solution 20 on side wall of the resist removal region 151 to make the dried film edge of the organic semiconductor solution 20 clean, neat and straight.

It should be noted that the above description takes the step of forming resist 15 and resist removal region 151 before the hydrophilic treatment of the substrate 01, namely, gate insulating layer 14 as the example. The above step of forming resist 15 and resist removal region 151 may also be conducted after the hydrophilic treatment of the substrate 01. In the present disclosure, there is no any limitation in this aspect, as long as the step of forming resist 15 and resist removal region 151 is conducted before the applying the organic semiconductor solution 20 on the substrate 01.

Furthermore, to be economical, the above light-radiation mask 16 may be identical to the mask for producing the active layer 10 which may be the mask for forming the resist removal region 151 on the resist 15.

S204: As shown in FIG. 16, the organic semiconductor solution 20 is dried to form an active layer 10 and the remaining resist 15 is removed.

S205: As shown in FIG. 17, a source electrode 11, a drain electrode 12 and a passivation layer 17 covering the above source electrode 11 and drain electrode 12 are formed on a baseplate having the active layer 10 by performing a patterning process.

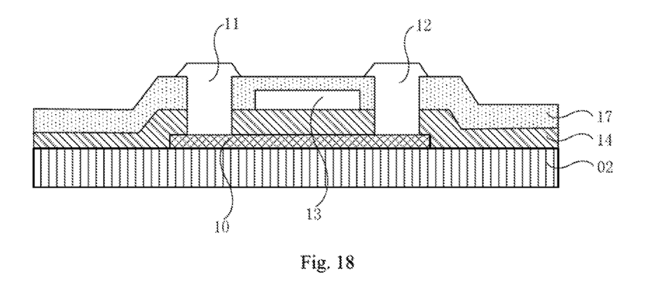

The process of producing the thin film transistor is described by taking the bottom-gate type thin film transistor as an example. When the thin film transistor is a top-gate type thin film transistor as shown in FIG. 18, during the production process of the top-gate type thin film transistor, the substrate 01 may also undergo a hydrophilic treatment by performing the UV-irradiation process described above. This production process differs from the production of the bottom-gate type thin film transistor in that for the top-gate type thin film transistor, the substrate baseplate 02 is used as the substrate 01.

Thus, after the substrate baseplate 02 undergoes the hydrophilic treatment by performing the UV-irradiation process, the organic semiconductor solution 20 may be applied on the substrate baseplate 02. The UV-irradiation process may be performed by a manner of forming a plurality of processing regions 101 having different hydrophilicities by moving the baseplate formed with the gate insulating layer 14 or the light-radiation mask 16 described above.

Further, the UV-irradiation process that does not move the baseplate or the light-radiation mask 16 may also be adopted. The UV-irradiation process may include:

For example, a light-radiation mask 16 may be firstly provided on one side of the substrate 01 to be irradiated. Then, within a same irradiation period, the substrate 01 is irradiated through a photic zone 162 on the light-radiation mask 16 by using a plurality of low pressure UV mercury lamps having different illumination intensities. As such, a plurality of low pressure UV mercury lamps having different illumination intensities may produce a plurality of processing regions 101 having different hydrophilicities on the substrate 01 within a same irradiation period.

For another example, the UV-irradiation process may include: the light-radiation mask 16 is provided on one side of the substrate 01 to be irradiated, then, the substrate 01 is irradiated via a photic zone 162 on the light-radiation mask 16 using a plurality of low pressure UV mercury lamps having identical illumination intensity but different illumination times. As such, a plurality of low pressure UV mercury lamps having identical illumination intensity may produce a plurality of processing regions 101 having different hydrophilicities on the substrate 01 within different irradiation periods.

In addition, the active layer 10 may be formed after the organic semiconductor solution 20 dries into film. A gate insulating layer 14 and a gate electrode 13 may be successively formed on the substrate baseplate 02 formed with the active layer 10 by performing a patterning process. Then, a passivation layer 17, a source electrode 11 and a drain electrode 12 may be successively formed on the substrate baseplate 02 formed with the gate electrode 13 by performing a patterning process. The procedures for producing the gate insulating layer 14, gate electrode 13, source electrode 11 and drain electrode 12 may be the same as above, and do not described repeatedly herein.

An embodiment of the present disclosure provides a thin film transistor produced by the above method, and the thin film transistor may include the source electrode 11 and drain electrode 12 as shown in FIG. 17. The thin film transistor may also include the substrate 01 as shown in FIG. 5, and the active layer 10 on the substrate 01.

Materials forming the active layer 10 may include an organic semiconductor material, and crystals of the above active layer 10 may grow in a direction that are parallel with the first direction X as shown in FIG. 8. The first direction X may be parallel with the transmission direction A of carriers in the thin film transistor.

The direction of most of the crystal boundaries in the active layer 10 may be parallel with the above first direction X. During the conduction of the thin film transistor, the transmission direction A of carriers may be parallel with the above first direction X. As such, there may be a great number of crystal boundaries that are parallel with the transmission direction A of carriers in the active layer 10. Accordingly, the number of crystal boundaries that are perpendicular to the transmission direction A of carriers may correspondingly decrease. The migration speed of the carriers is thus enhanced, and the aim may be achieved for enhancing the migration rate and conductivity of the thin film transistor.

When the above thin film transistor is a bottom-gate type thin film transistor, the thin film transistor as shown in FIG. 17, may also include a gate electrode 13 and a gate insulating layer 14 successively provided on the substrate baseplate 02. The gate insulating layer 14 may be substrate 01.

Alternatively, when the above thin film transistor is a top-gate type thin film transistor, the thin film transistor as shown in FIG. 18, may also include a gate insulating layer 14 and a gate electrode 13 successively provided on the substrate baseplate 02. The substrate baseplate 02 may be used as the substrate 01, and the active layer 10 may be sandwiched between the substrate baseplate 02 and the gate insulating layer 14.

An embodiment of the present disclosure provides an array baseplate, which may include any of the above thin film transistors. The array baseplate may have the same structure and beneficial effect as the thin film transistor provided in the previous embodiments. The previous embodiments have elaborated the structure and beneficial effect of the thin film transistor in details, and the same is not described repeatedly herein.

An embodiment of the present disclosure provides a display device which may include the aforementioned array baseplate. The display device may have the same structure and beneficial effect as the array baseplate provided in the previous embodiment. In the previous embodiment, the structure and beneficial effect of the array baseplate are described in details, and thus are not described repeatedly herein.

It should be noted that in the embodiment of the present disclosure, the display device may include at least a liquid crystal display device and an organic light-emitting diode display device. For example, the display device may be any product or part having a display function, such as a liquid crystal display device, a liquid crystal television, a digital photo frame, a cell phone or a tablet PC, etc.

The above descriptions are merely specific embodiments of the present disclosure. However, the protection scope of the present disclosure is not limited to the above. Any alteration or alternative ready to be thought of by a person of ordinary skills in the art within the technical scope revealed in the present disclosure would all be covered by the protection scope of the present disclosure.

1. A method for fabricating a thin film transistor, comprising:
forming an active layer, wherein forming the active layer comprises:
forming a plurality of processing regions on a substrate along a first direction, wherein any two adjacent processing regions have different hydrophilicities, and the first direction is parallel with a transmission direction of carriers in the thin film transistor; and
forming an active layer on the substrate to cover at least part of a junctional region between two adjacent processing regions.

2. The method according to claim 1, wherein forming the plurality of processing regions on the substrate comprises placing the plurality of processing regions successively along the first direction.

3. The method according to claim 1, wherein forming the plurality of processing regions on the substrate comprises enabling the hydrophilicities of the processing regions to change successively and gradually along the first direction.

4. The method according to claim 1, wherein the processing regions along a second direction covered by the active layer have an equal size, and the second direction is perpendicular to the first direction.

5. The method according to claim 1, wherein forming the plurality of processing regions on the substrate comprises forming the plurality of the processing regions on the substrate by performing an ultraviolet (UV)-irradiation process.

6. The method according to claim 5, wherein performing the UV-irradiation process comprises:
providing a light-radiation mask on a side of the substrate to be irradiated;
irradiating the substrate through a photic zone on the light-radiation mask with an UV mercury lamp; and
moving the substrate or the light-radiation mask along the first direction at a constant speed.

7. The method according to claim 5, wherein performing the UV-irradiation process comprises:
providing a light-radiation mask on a side of the substrate to be irradiated; and
irradiating the substrate through a photic zone on the light-radiation mask with a plurality of low pressure UV mercury lamps having different illumination intensities at a same radiation period.

8. The method according to claim 5, wherein performing the UV-irradiation process comprises:
providing a light-radiation mask on a side of the substrate to be irradiated; and
irradiating the substrate through a photic zone on the light-radiation mask with a plurality of low pressure UV mercury lamps having identical illumination intensity in different illumination periods.

9. The method according to claim 6, wherein the light-radiation mask is identical to a mask for producing the active layer.

10. The method according to claim 1, wherein forming the active layer on the substrate comprises:
applying an organic semiconductor solution on the substrate; and
causing the organic semiconductor solution to dry into a film to form the active layer.

11. The method according to claim 10, wherein, before applying the organic semiconductor solution on the substrate, the method further comprises:
forming a layer of resist on the substrate;
removing part of the resist by performing a patterning process to form a resist removal region; and
wherein applying the organic semiconductor solution on the substrate comprises applying the organic semiconductor solution on a position of the substrate corresponding to the resist removal region.

12. The method according to claim 1, wherein, before forming the plurality of processing regions on the substrate, the method further comprises:
forming, by performing a patterning process, a gate electrode and a gate insulating layer successively on a substrate baseplate wherein the gate insulating layer is the substrate.

13. The method for producing a thin film transistor according to claim 1, wherein the substrate is a substrate baseplate, and after the forming the active layer on the substrate to cover at least part of the junctional region between two adjacent processing regions, the method further comprises:
forming, by performing a patterning process, a gate insulating layer and a gate electrode successively on the substrate baseplate on which the active layer is formed; and
forming by performing the patterning process, the source electrode and the drain electrode on the substrate baseplate on which a gate electrode is formed.

14. The method according to claim 1, wherein the active layer is formed by using a polar semiconductor material.

15. The method according to claim 1, wherein a solvent of the organic semiconductor solution comprises a polar solvent.

16. A thin film transistor produced by the method according to any-one claim 1, comprising
a source electrode and a drain electrode, and
a substrate and an active layer on the substrate, wherein the active layer is formed by using an organic semiconductor material, and a growth direction of crystals of the active layer is parallel with a transmission direction of carriers in the thin film transistor.

17. The thin film transistor according to claim 16, further comprising:
a gate electrode and a gate insulating layer that are successively placed on a substrate baseplate, and wherein the gate insulating layer is the substrate.

18. The thin film transistor according to claim 16, further comprising:
a gate insulating layer and a gate electrode that are successively placed on the substrate baseplate, wherein the substrate baseplate is the substrate, and the active layer is located between the substrate baseplate and the gate insulating layer.

19. An array baseplate, comprising the thin film transistor according to claim 16.

20. A display device, comprising the array baseplate according to claim 19.
